(19) United States
(12) Patent Application Publication
(10) Pub. No.: US 2026/0362561 A1
(43) Pub. Date: Nov. 12, 2026

(54) COOKING APPLIANCE HEAT MANAGEMENT USER INTERFACE

(71) Applicant: Haier US Appliance Solutions, Inc., Wilmington, DE (US)

(72) Inventors: Benjamin Kline, Louisville, KY (US); Steven Michael Recio, Louisville, KY (US)

(21) Appl. No.: 19/199,452

(22) Filed: May 6, 2025

(51) Int. Cl. H05B 6/64; H05K 7/20; H05K 9/00

(52) U.S. Cl. CPC H05B 6/642; H05K 7/2039; H05K 9/002

(57) ABSTRACT

A cooking appliance includes a heating element, a controller, and a user interface panel. The controller is positioned proximate the user interface panel. The user interface panel includes a display, a bracket coupled to a back side of the display, a shield positioned between the display and the controller, and a thermal layer thermally coupling the display to the shield and the controller. As a result, heat flows between the controller and the display.

### FIELD OF THE INVENTION

The present subject matter relates generally to cooking appliances, such as range or oven appliances, and more specifically to heat management within cooking appliances.

### BACKGROUND OF THE INVENTION

Cooking appliances, such as range appliances, generally include heating elements for heating food, or heating cooking utensils, such as pots, pans, and griddles to cook food. Oven appliances generally include one or more enclosures for baking and broiling. In general, a user selects a desired heating level on a user interface of the cooking appliance, and operation of one or more of the heating elements or oven is performed at the selected heating level. For example, certain range appliances include electric heating elements, where the range appliance may operate the electric heating elements at a predetermined power output corresponding to a selected heating level. As another example, some range appliances include gas burners as heating elements, where the flow of gas may be regulated to provide the selected heating level.

Cooking appliances typically include a controller for components such as a user interface (UI), such as a control panel and/or a display with input selectors. In typical cooking appliances, the controller receives undesired heat from the heating elements, such as due to the positioning of the controller relative to the heating elements. A typical method of cooling the controller is to add metal heat shields around the controller, but the metal heat shields can be expensive and can increase the complexity of manufacturing. An alternative method of cooling the controller includes adding fan(s), which may also be expensive and can increase the complexity of manufacturing.

Accordingly, a cooking appliance which includes a system for cooling the controller to obviate some of the above issues of cooktop appliances would be beneficial and advantageous. In particular, an inexpensive and less complex cooking appliance configured to cool the controller would be particularly beneficial.

### BRIEF DESCRIPTION OF THE INVENTION

Aspects and advantages of the invention will be set forth in part in the following description, or may be obvious from the description, or may be learned through practice of the invention.

In one example embodiment, a cooking appliance is provided. The cooking appliance defines a vertical direction, a lateral direction, and a transverse direction. The vertical, lateral, and transverse directions are mutually perpendicular. The cooking appliance includes a heating element, a controller in operative communication with the heating element, and a user interface panel. The controller is positioned proximate the user interface panel. The user interface panel includes a display, a bracket coupled to a back side of the display, and a shield positioned between the display and the controller. The shield defines a first side and a second side opposing the first side. A first thermal layer is on the first side of the shield. The first thermal layer thermally couples the display to the shield. A second thermal layer is on the second side of the shield. The second thermal layer thermally couples the shield to the controller. As a result, heat flows outward from the controller, through the second thermal layer, the shield, and the first thermal layer towards the display.

In another example embodiment, a cooking appliance is provided. The cooking appliance includes a heating element, a controller, and a user interface panel. The controller is positioned proximate the user interface panel. The user interface panel includes a display, a bracket coupled to a back side of the display, a shield positioned between the display and the controller, and a thermal layer thermally coupling the display to the shield and the controller. As a result, heat flows between the controller and the display.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures.

FIG. 1 provides a front, perspective view of a range appliance according to an example embodiment of the present disclosure.

FIG. 2 provides a top, plan view of the example range appliance of FIG. 1.

FIG. 3 provides a perspective view of a cooktop of a range appliance according to an example embodiment of the present disclosure.

FIG. 4 provides a perspective view of a burner for a range appliance according to an example embodiment of the present disclosure.

FIG. 5 provides a front view of a user interface of a range appliance according to an example embodiment of the present disclosure.

FIG. 6 provides a rear perspective view of a display and a controller of the user interface of FIG. 5.

FIG. 7 provides a perspective view of the display and the controller of FIG. 6, with the controller rotated to show additional details according to an example embodiment of the present disclosure.

FIG. 8 provides a perspective view of an example bracket of the user interface of FIG. 5.

FIG. 9 provides a side, sectional, schematic view of the user interface of FIG. 5.

Repeat use of reference characters in the present specification and drawings is intended to represent the same or analogous features or elements of the present invention.

### DETAILED DESCRIPTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope of the invention. For instance, features illustrated or described as part of one embodiment can be used with another embodiment to yield a still further embodiment. Thus, it is intended that the present invention covers such modifications and variations as come within the scope of the appended claims and their equivalents.

As used herein, the term “or” is generally intended to be inclusive (i.e., “A or B” is intended to mean “A or B or both”). The terms “first,” “second,” and “third” may be used interchangeably to distinguish one component from another and are not intended to signify location or importance of the individual components. The terms “upstream” and “downstream” refer to the relative flow direction with respect to fluid flow in a fluid pathway. For example, “upstream” refers to the flow direction from which the fluid flows, and “downstream” refers to the flow direction to which the fluid flows.

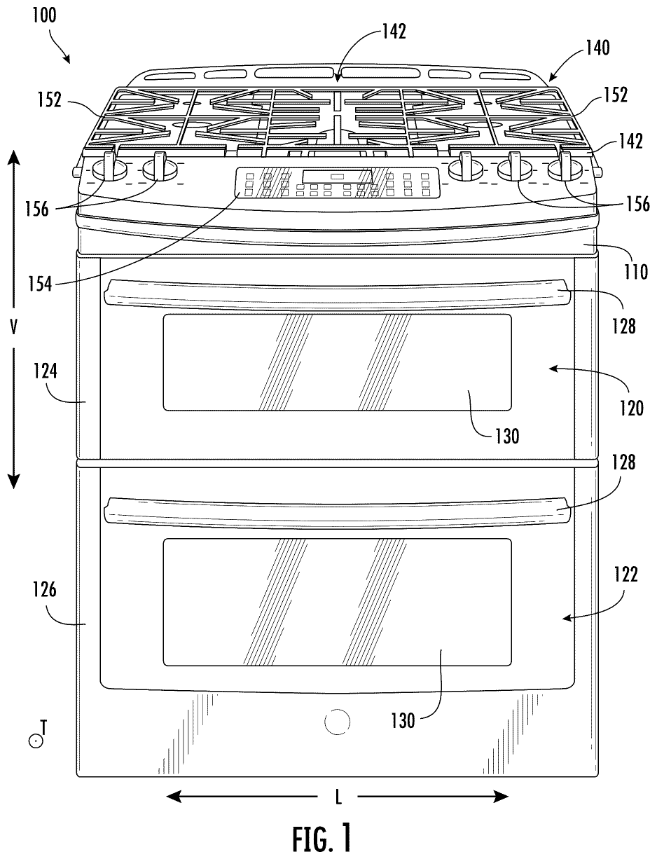

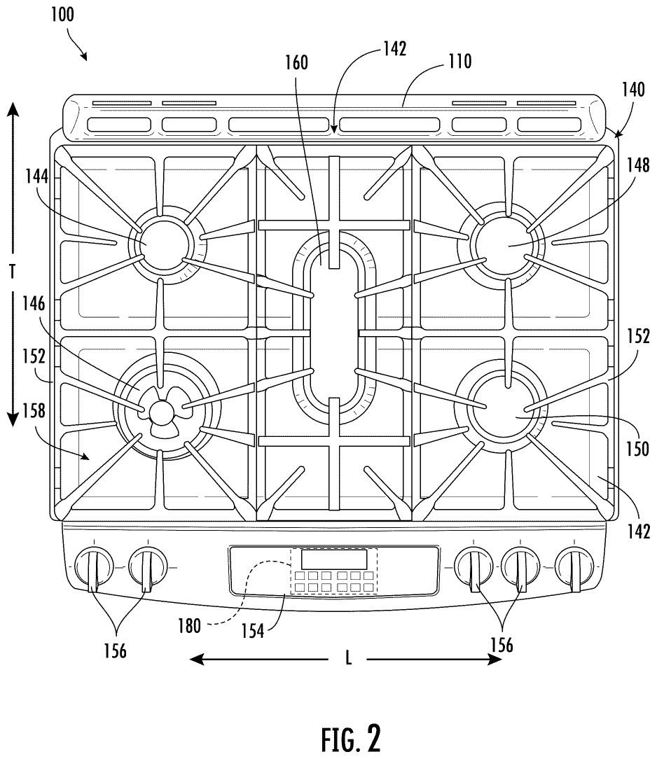

Turning now to the figures, FIG. 1 provides a front, perspective view of a cooking appliance, e.g., range appliance 100, as may be employed with the present disclosure. FIG. 2 provides a top, plan view of range appliance 100. In general, range appliance 100 may define a vertical direction V, a lateral direction L, and a transverse direction T. The vertical, lateral, and transverse directions are mutually perpendicular. Range appliance 100 includes an insulated cabinet 110. Cabinet 110 defines an upper cooking chamber 120 and a lower cooking chamber 122. Thus, range appliance 100 is generally referred to as a double oven range appliance. As will be understood by those skilled in the art, range appliance 100 is provided by way of example only, and the present disclosure may be used in any suitable cooking appliance, e.g., a single oven range appliance, an oven appliance, a standalone cooktop appliance, or a microwave appliance. Thus, the example embodiment shown in FIG. 1 is not intended to limit the present disclosure to any particular cooking appliance configuration or arrangement.

Upper and lower cooking chambers 120 and 122 are configured for the receipt of one or more food items to be cooked. Range appliance 100 includes an upper door 124 and a lower door 126 rotatably attached to cabinet 110 in order to permit selective access to upper cooking chamber 120 and lower cooking chamber 122, respectively. Handles 128 are mounted to upper and lower doors 124 and 126 to assist a user with opening and closing doors 124 and 126 in order to access cooking chambers 120 and 122. As an example, a user can pull on handle 128 mounted to upper door 124 to open or close upper door 124 and access upper cooking chamber 120. Glass windowpanes 130 provide for viewing the contents of upper and lower cooking chambers 120 and 122 when doors 124 and 126 are closed and also assist with insulating upper and lower cooking chambers 120 and 122. Heating elements (not shown), such as electric resistance heating elements, gas burners, microwave heating elements, halogen heating elements, or suitable combinations thereof, are positioned within upper cooking chamber 120 and lower cooking chamber 122 for heating upper cooking chamber 120 and lower cooking chamber 122.

Range appliance 100 also includes a cooktop 140. Cooktop 140 is positioned at or adjacent a top portion of cabinet 110. Thus, cooktop 140 is positioned above upper and lower cooking chambers 120 and 122. Cooktop 140 includes a top panel 142. By way of example, top panel 142 may be constructed of glass, ceramics, enameled steel, and combinations thereof. Moreover, top panel 142 may be formed as a unitary, single piece or, alternatively, as multiple discrete pieces joined together.

For range appliance 100, a utensil holding food or cooking liquids (e.g., oil, water, etc.) may be placed onto grates 152 at a location of any of the heating elements, e.g., burner assemblies 144, 146, 148, 150. Burner assemblies 144, 146, 148, 150 provide thermal energy to cooking utensils on grates 152. As shown in FIG. 1, burners assemblies 144, 146, 148, 150 can be configured in various sizes so as to provide, for example, for the receipt of cooking utensils (e.g., pots, pans, etc.) of various sizes and configurations and to provide different heat inputs for such cooking utensils. Grates 152 may be supported on a top surface 158 of top panel 142. In optional embodiments, range appliance 100 includes a griddle burner assembly 160 positioned at a middle portion of top panel 142, as may be seen in FIG. 2. A griddle may be positioned on grates 152 and heated with griddle burner assembly 160.

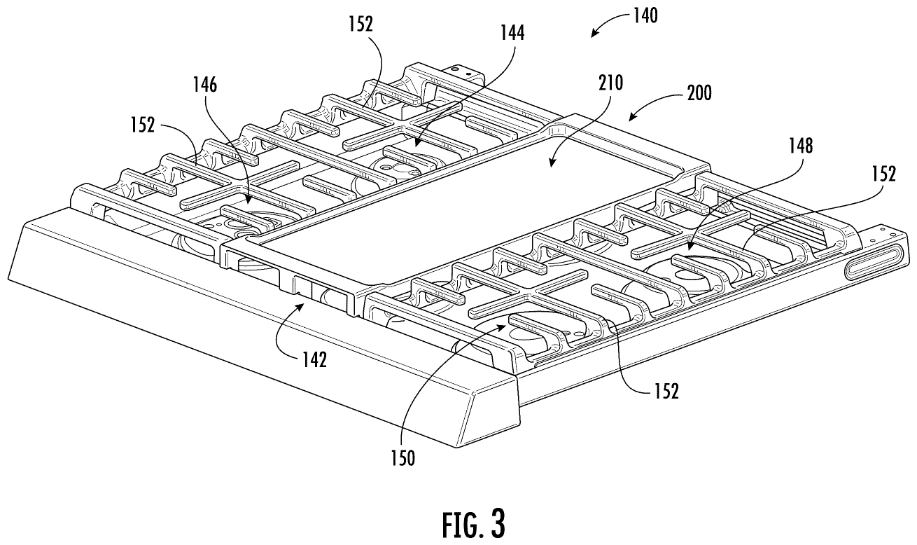

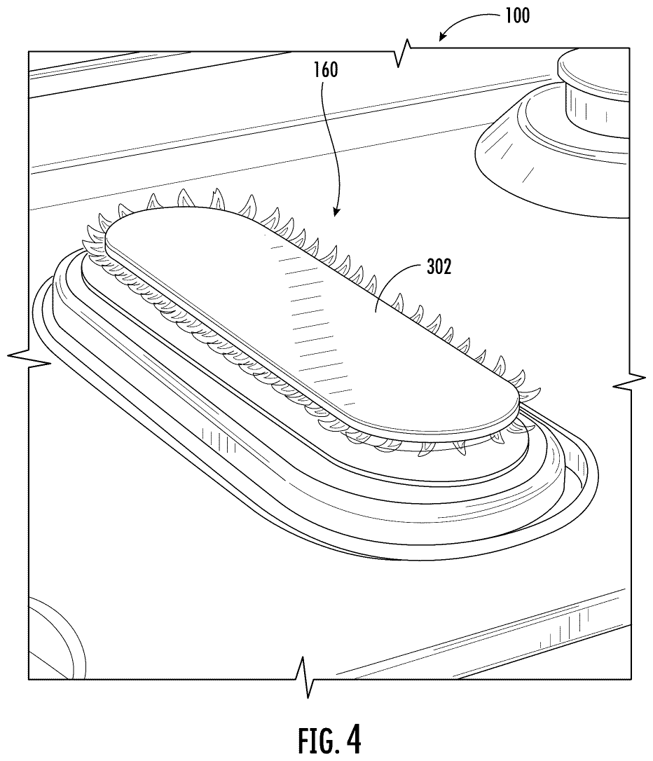

Referring briefly to FIGS. 3 through 4, an embodiment of a griddle 200 is provided. FIGS. 3 through 4 provide perspective views of an example cooktop 140 for a range appliance, such as range appliance 100 depicted and described in regard to FIGS. 1 and 2. Embodiments of cooktop 140 may include a plurality of griddle burner assemblies 160, or a single griddle burner assembly 160, such as depicted in FIG. 4. In various embodiments, burner assembly 160 may be configured as an elongated burner, such as may have a stadium perimeter, beneath griddle 200 in order to heat a cooking surface 210 of griddle 200.

Referring again to FIGS. 1 and 2, a user interface panel 154 is located within convenient reach of a user of the range appliance 100. For this example embodiment, user interface panel 154 includes input selectors 156, such as knobs or buttons, that may be associated with one or more of burner assemblies 144, 146, 148, 150 and griddle burner assembly 160. Input selectors 156 may allow the user to activate each burner assembly and determine the amount of heat input provided by each burner assembly 144, 146, 148, 150 and griddle burner assembly 160 to a cooking utensil located thereon. User interface panel 154 may also be provided with one or more graphical display devices, as will be described below, that deliver certain information to the user such as, for example, whether a particular burner assembly is activated or the rate at which the burner assembly is set.

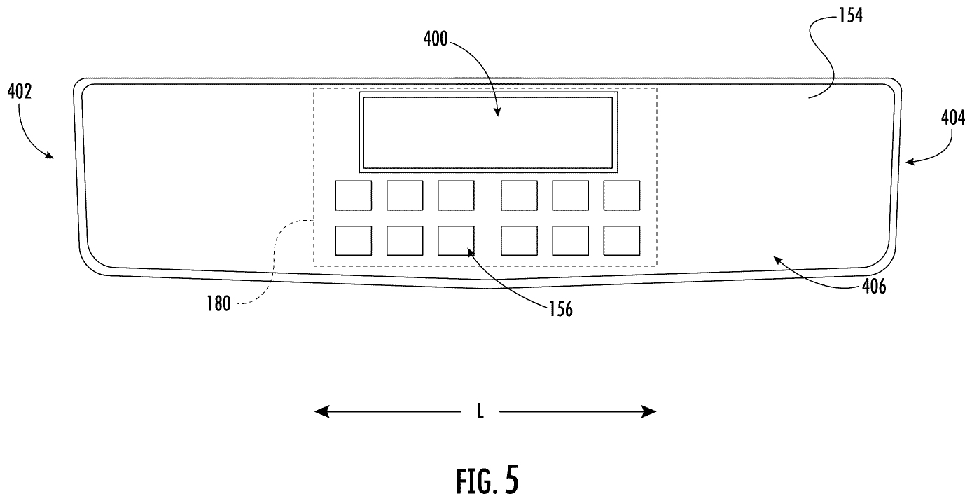

Although shown with knobs, it should be understood that input selectors 156 and the configuration of range appliance 100 shown in FIG. 1 are provided by way of example only. More specifically, user interface panel 154 may include various input selectors 156, such as one or more of a variety of touch-type controls, electrical, mechanical, or electro-mechanical input devices including rotary dials, push buttons, and touch pads. The user interface panel 154 may include a display 400 (FIG. 5), such as a digital or analog display device designed to provide operational feedback to a user, as will be further explained below.

Further, range appliance 100 may include a controller 180. Controller 180 may include a plurality of electrical components configured to permit operation of range appliance 100 and various components therein (e.g., burner assemblies). In particular, controller 180 may be at least partially located within user interface panel 154. For instance, controller 180 may be or may include a microcontroller, as would be understood, including one or more processing devices or memory devices in a single integrated circuit. For instance, controller 180 may include one or more printed circuit boards (PCBs) with various components (e.g., microcontroller or other controller, processing devices, and/or memory devices) coupled thereto, as would be understood by those of ordinary skill in the art. Thus, for example, controller 180 may be partially located within the user interface panel 154 in that one of several PCBs which collectively provide the controller 180 is located within the user interface panel 154 whereas one or more other PCBs are spaced apart from the user interface panel 154. Alternatively, the entire controller 180 (such as all of the PCBs making up the controller 180 or a single PCB which is the only PCB of the controller 180) may be located within the user interface panel 154.

As used herein, the terms “control board,” “processing device,” “computing device,” “controller,” or the like may generally refer to any suitable processing device, such as a general or special purpose microprocessor, a microcontroller, an integrated circuit, an application specific integrated circuit (ASIC), a digital signal processor (DSP), a field-programmable gate array (FPGA), a logic device, one or more central processing units (CPUs), a graphics processing units (GPUs), processing units performing other specialized calculations, semiconductor devices, etc. Alternatively, controller 180 may be constructed without using a microprocessor, e.g., using a combination of discrete analog and/or digital logic circuitry (such as switches, amplifiers, integrators, comparators, flip-flops, AND/OR gates, and the like) to perform control functionality instead of relying upon software. In addition, these “controllers” are not necessarily restricted to a single element but may include any suitable number, type, and configuration of devices integrated in any suitable manner to facilitate appliance operation, e.g., multiple elements in multiple locations within the appliance or in a single location, as described above.

Controller 180 may include, or be associated with, one or more memory elements or non-transitory computer-readable storage mediums, such as RAM, ROM, EEPROM, EPROM, flash memory devices, magnetic disks, or other suitable memory devices (including combinations thereof). These memory devices may be a separate component from the processor or may be included onboard within the processor. In addition, these memory devices can store information and/or data accessible by the one or more processors, including instructions that can be executed by the one or more processors. It should be appreciated that the instructions can be software written in any suitable programming language or can be implemented in hardware. Additionally, or alternatively, the instructions can be executed logically and/or virtually using separate threads on one or more processors.

For example, controller 180 may be operable to execute programming instructions or micro-control code associated with operating range appliance 100. In this regard, the instructions may be software or any set of instructions that when executed by the processing device, cause the processing device to perform operations, such as running one or more software applications, displaying a user interface, receiving user input, processing user input, etc. Moreover, it should be noted that controller 180 as disclosed herein is capable of and may be operable to perform any methods, method steps, or portions of methods.

The memory devices may also store data that can be retrieved, manipulated, created, or stored by the one or more processors or portions of controller 180. The data can include, for instance, data to facilitate performance of methods. The data can be stored locally (e.g., on controller 180) in one or more databases and/or may be split up so that the data is stored in multiple locations. In addition, or alternatively, the one or more database(s) can be connected to a remote user interface (not shown) through any suitable network(s), such as through a high bandwidth local area network (LAN) or wide area network (WAN). In this regard, for example, controller 180 may further include a communication module or interface that may be used to communicate with one or more other component(s) of range appliance 100, controller 180, an external appliance controller, an external device, or any other suitable device, e.g., via any suitable communication lines or network(s) and using any suitable communication protocol. The communication interface can include any suitable components for interfacing with one or more network(s), including for example, transmitters, receivers, ports, controllers, antennas, or other suitable components.

Turning now to FIG. 5, provided is a front view of user interface panel 154 according to an example embodiment of the present subject matter. In general, user interface panel 154 may be a glass panel, where display 400 is positioned behind user interface panel 154 (e.g., relative to a user positioned in front of range appliance 100) and is visible to a user through the glass of user interface panel 154. In general, input selectors 156 and display 400 may be integrated into a single device, e.g., including one or more of a touchscreen interface, a capacitive touch panel, a liquid-crystal display (LCD), a plasma display panel (PDP), or other informational or interactive displays. Accordingly, as described above, input selectors 156 may include a variety of touch-type controls, such as electrical or mechanical, positioned on or under the glass of user interface panel 154.

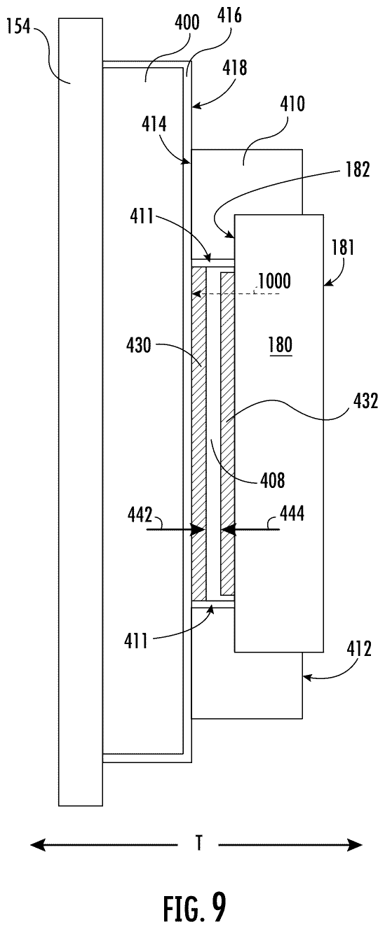

In general, at least a portion of the controller 180 may be positioned behind display 400, e.g., relative to a user positioned in front of range appliance 100, similar to display 400 being positioned behind user interface panel 154. For example, referring briefly to FIG. 9, with respect to the transverse direction T, user interface panel 154 may face outwards toward a user, display 400 may be positioned behind user interface panel 154, and controller 180 may generally be positioned behind display 400.

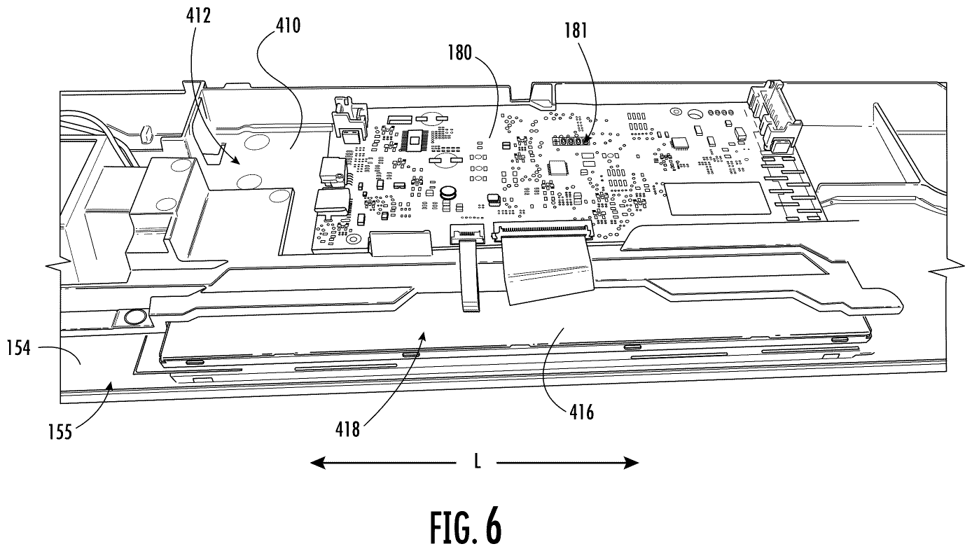

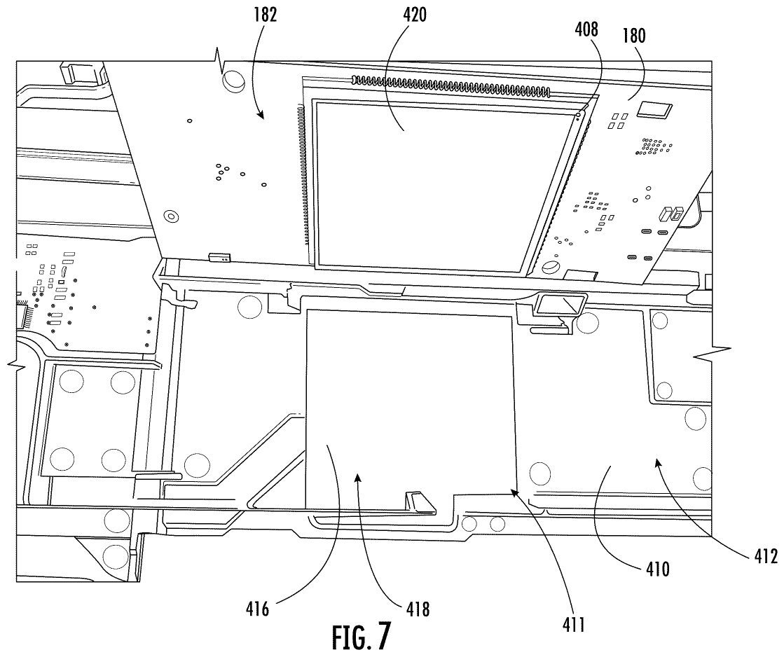

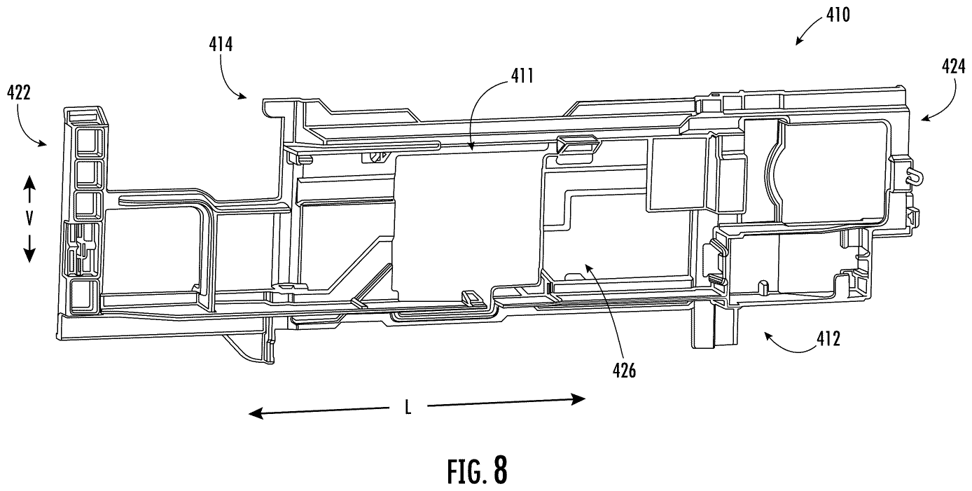

Referring now to FIGS. 6 through 9, display 400 may generally include a display frame 416. For example, display frame 416 may be a metal (or other thermally conductive material) frame enclosing display 400 against user interface panel 154. In general, as seen in FIG. 6, a bracket 410 may be coupled to a back side 418 of display frame 416, e.g., behind display 400. Bracket 410, as best seen in FIG. 8, may generally be defined between a front side 414, a back side 412, a first side 422, and a second side 424. In general, bracket 410 defines a housing portion 426 configured to receive controller 180 of cooking appliance 100, e.g., holding controller 180 within bracket 410. As will be explained further below with reference to FIGS. 7 through 9, bracket 410 of user interface panel 154 defines an opening 411 extending in the transverse direction T between front side 414 of bracket 410 and back side 412 of bracket 410.

In general, as may be seen in FIGS. 7 and 9, a shield 408 may be positioned between display 400 and controller 180. In general, shield 408 is defined between a first side 442 and a second side 444 opposing first side 442. In particular, shield 408 of user interface panel 154 is a radio frequency shield for reducing radio frequency interference (RFI). One of skill in the art would understand that providing radio frequency interference shielding around electronics of a device may reduce or prevent disruption of the operation of the device, such as providing shield 408 between display 400 and controller 180, to reduce/prevent disruption of the operation of range appliance 100.

As stated above, in typical cooking appliances, the controller may receive undesired heat from the heating elements, and overheating the controller may result in operational issues of the cooking appliance. In general, the present example embodiment includes a thermal layer 420 (FIG. 7) that may thermally couple display 400, e.g., back side 418 of display frame 416, to shield 408 and to controller 180. As will be explained further below, heat may generally flow between controller 180 and display 400, such as to provide a heat sink, or cooling, for controller 180, e.g., the heat flow between controller 180 and display 400 may be predominantly or entirely away from the controller 180 to thereby cool the controller 180. In general, thermal layer 420 (e.g., or first thermal layer 430 and second thermal layer 432, described below) may be one or more of thermal pads or thermal paste. One of skill in the art would understand that thermal pastes and thermal pads generally facilitate heat transfer between components.

Turning particularly to FIG. 9, provided is a side, sectional view of the user interface panel 154. FIG. 9 is provided as a schematic representation of user interface panel 154, and user interface panel 154 and various components of user interface panel 154 may not be represented to precise scale, orientation, and/or position. FIG. 9 is provided for the purpose of explanation of the current subject matter only and is not intending to be limiting to certain aspects of the current subject matter, such as scale, orientation, and/or position.

In particular, as may be seen in FIG. 9, a first thermal layer 430 may be positioned on first side 442 of shield 408. In general, first thermal layer 430 may thermally couple display 400, e.g., back side 418 of display frame 416, to shield 408. Additionally, a second thermal layer 432 may be positioned on second side 444 of shield 408. In general, second thermal layer 432 may thermally couple shield 408 to controller 180. In some example embodiments, shield 408 may mechanically couple to controller 180, such as by any suitable fasteners. In general, some example embodiments may include shield 408 fully encapsulating second thermal layer 432 against controller 180. As such, controller 180 may be in thermal communication with display frame 416 of display 400, and thus with the glass of user interface panel 154. In particular, heat may flow outward, e.g., as indicated by a flow of heat 1000, from controller 180, through second thermal layer 432, shield 408, and first thermal layer 430 towards display 400.

In general, first thermal layer 430 positioned on first side 442 of shield 408 may extend through opening 411 of bracket 410 in order to contact display frame 416. As illustrated in FIG. 9, one or more of first thermal layer 430, shield 408, and second thermal layer 432 may generally extend through or within opening 411 of bracket 410, such that controller 180 is thermally coupled to display frame 416 of display 400 through bracket 410. User interface panel 154 may generally be cooler than controller 180, e.g., user interface panel 154 may be both of positioned further way from the heating elements, burner assemblies 144, 146, 148, 150, of range appliance 100 than controller 180 and exposed to open air in front of appliance 100. As such, heat from controller 180 may be drawn out via first thermal layer 430, shield 408, and second thermal layer 432 through opening 411 of bracket 410 to cool controller 180.

As may be seen from the above, a cooking appliance, such as a range appliance may include a system for cooling the controller. In particular, a user interface panel of the cooking appliance may include a controller thermally coupled to a display component of the user interface panel, such as via thermal pad(s) positioned between the display component and the user interface panel. Accordingly, undesired heat at the controller, such as heat received from heating elements of the cooking appliance, may flow outwards from the controller to the display component to advantageously cool down the controller. As such, providing thermal pad(s) to thermally couple the controller to the display component may advantageously provide an inexpensive and easy to manufacture way to cool the controller, in comparison to typical methods.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A cooking appliance defining a vertical direction, a lateral direction, and a transverse direction, the vertical, lateral, and transverse directions being mutually perpendicular, the cooking appliance comprising:
a heating element;
a controller in operative communication with the heating element; and
a user interface panel, the controller positioned proximate the user interface panel, the user interface panel comprising:
a display;
a bracket coupled to a back side of the display;
a shield positioned between the display and the controller, the shield defining a first side and a second side opposing the first side;
a first thermal layer on the first side of the shield, wherein the first thermal layer thermally couples the display to the shield; and
a second thermal layer on the second side of the shield, wherein the second thermal layer thermally couples the shield to the controller,
wherein heat flows outward from the controller, through the second thermal layer, the shield, and the first thermal layer towards the display.

2. The cooking appliance of claim 1, wherein the bracket of the user interface panel defines an opening, wherein the first thermal layer on the first side of the shield extends through the opening of the bracket to contact the display.

3. The cooking appliance of claim 1, wherein the bracket of the user interface panel defines a housing portion configured to receive the controller of the cooking appliance within the bracket.

4. The cooking appliance of claim 1, wherein the display comprises a display frame, wherein the bracket is coupled to the display frame of the display, and wherein the first thermal layer thermally couples the display frame of the display to the shield.

5. The cooking appliance of claim 1, wherein each of the first thermal layer and the second thermal layer comprises one or more of thermal pads and thermal paste.

6. The cooking appliance of claim 1, wherein the display of the user interface panel comprises a liquid-crystal display.

7. The cooking appliance of claim 1, wherein the user interface panel comprises a glass panel.

8. The cooking appliance of claim 1, wherein the shield of the user interface panel comprises a radio frequency shield.

9. The cooking appliance of claim 1, wherein the cooking appliance is one of a range appliance, an oven appliance, a cooktop appliance, or a microwave appliance.

10. A cooking appliance, comprising:
a heating element;
a controller; and
a user interface panel, the controller positioned proximate the user interface panel, the user interface panel comprising:
a display;
a bracket coupled to a back side of the display;
a shield positioned between the display and the controller; and
a thermal layer, the display thermally coupled to the shield and the controller via the thermal layer, whereby heat flows between the controller and the display.

11. The cooking appliance of claim 10, wherein the bracket of the user interface panel defines an opening, wherein the thermal layer extends through the opening of the bracket to contact the display.

12. The cooking appliance of claim 10, wherein the bracket of the user interface panel defines a housing portion configured to receive the controller of the cooking appliance within the bracket.

13. The cooking appliance of claim 10, wherein the display comprises a display frame, wherein the bracket couples to the display frame of the display, and wherein the thermal layer thermally couples the display frame of the display to the shield.

14. The cooking appliance of claim 10, wherein the thermal layer comprises one or more of a thermal pad or a thermal paste.

15. The cooking appliance of claim 10, wherein the display of the user interface panel comprises a liquid-crystal display.

16. The cooking appliance of claim 10, wherein the user interface panel comprises a glass panel.

17. The cooking appliance of claim 10, wherein the shield of the user interface panel comprises a radio frequency shield.

18. The cooking appliance of claim 10, wherein the cooking appliance is one of a range appliance, an oven appliance, a cooktop appliance, or a microwave appliance.
